(19) United States
(12) Patent Application Publication
(10) Pub. No.: US 2013/0141837 A1
(43) Pub. Date: Jun. 6, 2013

(54) MULTILAYER CERAMIC ELECTRONIC PART

(71) Applicants: Chung Eun Lee, Suwon (KR); Seon Cheol Park, Hwaseong (KR); Jae Yeol Choi, Seongnam (KR); Sang Hoon Kwon, Suwon (KR)

(72) Inventors: Chung Eun Lee, Suwon (KR); Seon Cheol Park, Hwaseong (KR); Jae Yeol Choi, Seongnam (KR); Sang Hoon Kwon, Suwon (KR)

(73) Assignee: SAMSUNG ELECTRO-MECHANICS CO., LTD.

(21) Appl. No.: 13/403,464

(22) Filed: Feb. 23, 2012

(30) Foreign Application Priority Data
Dec. 6, 2011 (KR) 10-2011-0129649

(51) Int. Cl. H01G 4/12; H01C 7/10; H01L 41/083

(52) U.S. Cl. 361/321.2; 310/367; 338/22 R

(57) ABSTRACT

There is provided a 1005-sized or smaller multilayer ceramic electronic part, including: a ceramic body having internal electrodes having a directivity perpendicular to a printed circuit board; and external electrodes formed on both end portions of the ceramic body and electrically connected to the internal electrodes each including an active area part and a lead part, the active area parts facing each other to contribute to forming capacitance, and the lead part having a width smaller than that of the active area part, and wherein when a width of the active area part is defined as WLa, a width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.12.

### CROSS-REFERENCE TO RELATED APPLICATIONS

This application claims the priority of Korean Patent Application No. 10-2011-0129649 filed on Dec. 6, 2011, in the Korean Intellectual Property Office, the disclosure of which is incorporated herein by reference.

### BACKGROUND OF THE INVENTION

1. Field of the Invention

The present invention relates to a multilayer ceramic electronic part.

2. Description of the Related Art

A multilayer ceramic capacitor is one of various multilayer ceramic electronic parts, having internal electrodes formed between respective dielectric layers in the multilayer ceramic capacitor.

As miniaturization and multifunctionalization of electronic products are demanded, chip type multilayer capacitors mounted in electronic products are also required to be miniaturized and have high capacitance.

In order to realize miniaturization and high capacitance in the multilayer ceramic capacitor, a method of reducing the thickness of dielectric layers interposed between internal electrodes within a ceramic body, or a method of increasing the number of internal electrode laminations is used.

As such, the methods for miniaturizing and providing a multilayer ceramic capacitor with high capacitance are used, and thus, internal electrode formation density internal is increased in an active area occupied by the internal electrodes within the multilayer ceramic capacitor.

When the formation density of the internal electrodes is increased in the active area, internal defects such as cracking and the like may be brought about at the interface between the dielectric layer and the internal electrode by even small change in internal stress through an action such as the cutting or sintering of ceramic green sheets.

In a case in which internal defects such as cracking and the like occur at the interface between the dielectric layer and the internal electrode, desired characteristics, such as the securing of capacitance, cannot be obtained and reliability of multilayer ceramic electronic parts such as a multilayer ceramic capacitor and the like may be lowered.

### SUMMARY OF THE INVENTION

An aspect of the present invention provides a multilayer ceramic electronic part having relatively reduced internal defects or improved characteristics even in the case of miniaturization and high capacitance, by relieving internal stress.

According to an aspect of the present invention, there is provided a 1005-sized or smaller multilayer ceramic electronic part, including: a ceramic body having internal electrodes laminated therein, the internal electrodes having a directivity perpendicular to a printed circuit board; and external electrodes formed on both end portions in a longitudinal direction of the ceramic body and electrically connected to the internal electrodes, wherein each of the internal electrodes includes an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part, and wherein when a width of the active area part is defined as WLa, the width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.12.

The lead part may have a square shape having the same width.

The lead part may have a tapered shape, a width of the tapered shape being reduced toward a direction in which the lead part is withdrawn to the external electrode.

The ceramic body may have a length, a width, and a thickness of 1.0±0.20 mm, 0.5±0.20 mm, and 0.5±0.20 mm, respectively, or 0.6±0.15 mm, 0.3±0.15 mm, and 0.3±0.15 mm, respectively.

The internal electrodes may be laminated in 170 layers to 500 layers in the ceramic body.

According to another aspect of the present invention, there is provided a multilayer ceramic electronic part of 0603 size, including: a ceramic body having internal electrodes laminated therein, the internal electrodes having a directivity parallel with a printed circuit board; and external electrodes formed on both end portions in a longitudinal direction of the ceramic body and electrically connected to the internal electrodes, wherein each of the internal electrodes includes an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part, and wherein when a width of the active area part is defined as WLa, a width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦00.25.

The lead part may have a square shape having the same width.

The lead part may have a tapered shape, a width of the tapered shape being reduced toward a direction in which the lead part is withdrawn to the external electrode.

The ceramic body may have a length, a width, and a thickness of 0.6±0.15 mm, 0.3±0.15 mm, and 0.3±0.15 mm, respectively.

The internal electrodes may be laminated in 170 layers to 500 layers in the ceramic body.

According to another aspect of the present invention, there is provided a multilayer ceramic electronic part of 1005 size, including: a ceramic body having internal electrodes laminated therein, the internal electrodes having a directivity parallel with a printed circuit board; and external electrodes formed on both end portions in a longitudinal direction of the ceramic body and electrically connected to the internal electrodes, wherein each of the internal electrodes includes an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part, and wherein when a width of the active area part is defined as WLa, a width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.27.

The lead part may have a square shape having the same width.

The lead part may have a tapered shape, a width of the tapered shape being reduced toward a direction in which the lead part is withdrawn to the external electrode.

The ceramic body may have a length, a width, and a thickness of 1.0±0.20 mm, 0.5±0.20 mm, and 0.5±0.20 mm, respectively.

The internal electrodes may be laminated in 170 layers to 500 layers in the ceramic body.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a schematic perspective view of a state in which a multilayer ceramic capacitor is mounted on a printed circuit board such that internal electrodes are in parallel with the printed circuit board, according to an embodiment of the present invention, and FIG. 1B is a cross-sectional view of a state in which the multilayer ceramic capacitor of FIG. 1A is mounted on the printed circuit board;

FIG. 2A is a schematic perspective view of a state in which a multilayer ceramic capacitor is mounted on a printed circuit board such that internal electrodes are perpendicular to the printed circuit board, according to another embodiment of the present invention, and FIG. 2B is a cross-sectional view of a state in which the multilayer ceramic capacitor of FIG. 2A is mounted on the printed circuit board;

FIG. 3 is a cross-sectional view in a length-thickness direction of a multilayer ceramic capacitor according to an embodiment of the present invention;

FIG. 4 is a cross-sectional view in a width-thickness direction of a multilayer ceramic capacitor according to an embodiment of the present invention;

FIG. 5 is a schematic exploded perspective view of a multilayer ceramic capacitor according to an embodiment of the present invention;

FIG. 6 is a schematic plane view in a length-width direction for measuring the bottleneck rate of a lead part of a multilayer ceramic capacitor according to an embodiment of the present invention; and

FIG. 7 is a schematic plane view in a length-width direction for measuring the bottleneck rate of a lead part of a multilayer ceramic capacitor according to another embodiment of the present invention.

### DETAILED DESCRIPTION OF THE EMBODIMENTS

Embodiments of the present invention will now be described in detail with reference to the accompanying drawings.

However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, but those are construed as being included in the spirit of the present invention.

Further, like reference numerals will be used to designate like components having similar functions throughout the drawings within the scope of the present invention.

A multilayer ceramic electronic part according to an embodiment of the present invention may be appropriately used in a multilayer ceramic capacitor, a multilayer varistor, a thermistor, a piezoelectric element, a multilayer board, or the like, which employs dielectric layers therein which are ceramic layers, and has a structure in which the internal electrodes face each other with the dielectric layer therebetween.

Hereinafter, embodiments of the present invention will be described by using a multilayer ceramic capacitor.

Multilayer Ceramic Capacitor and Printed Circuit Board Having the Multilayer Ceramic Capacitor Mounted thereon

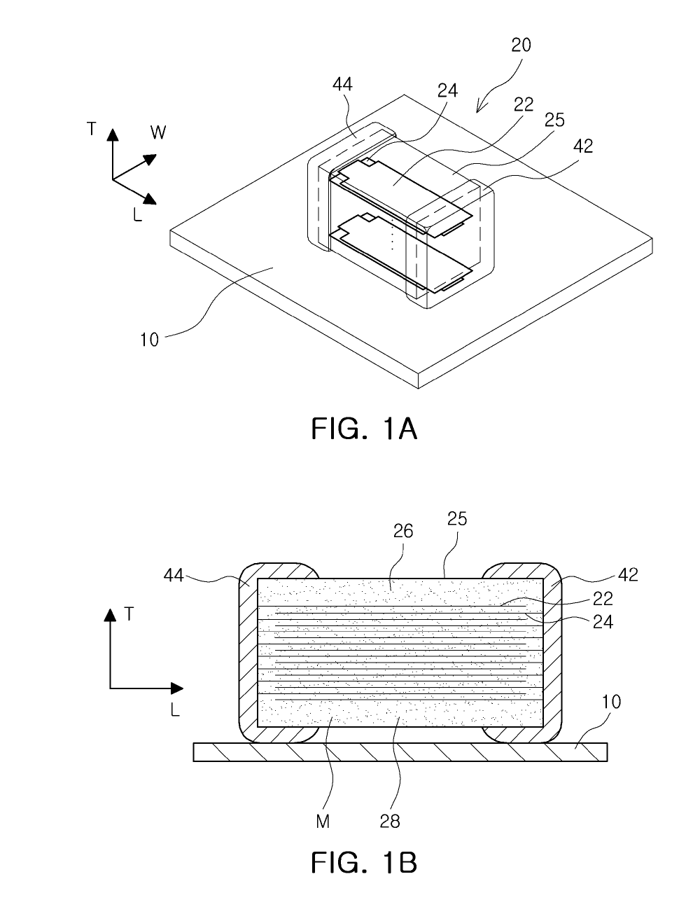

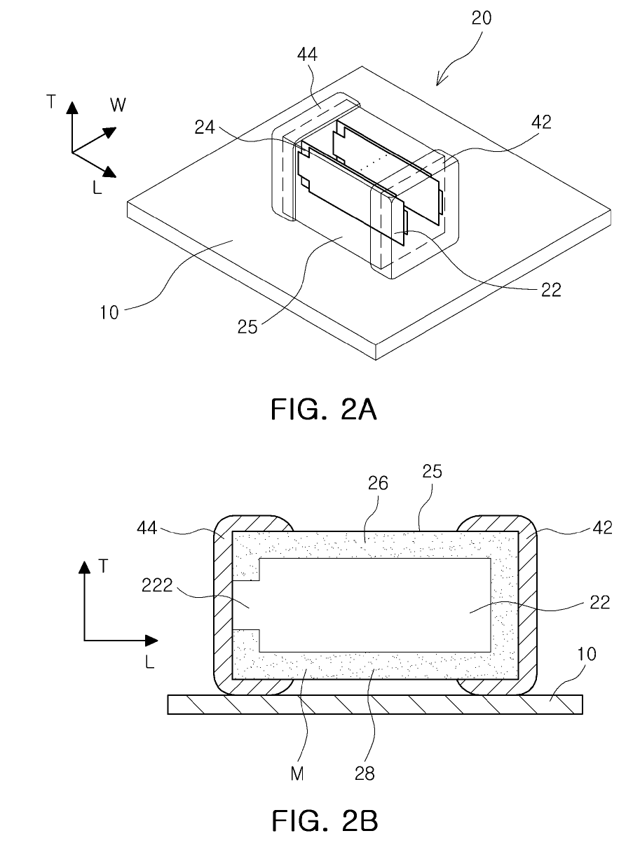

FIG. 1A is a schematic perspective view of a state in which a multilayer ceramic capacitor is mounted on a printed circuit board such that internal electrodes are parallel with the printed circuit board, according to an embodiment of the present invention, and FIG. 1B is a cross-sectional view of a state in which the multilayer ceramic capacitor of FIG. 1A is mounted on the printed circuit board; and FIG. 2A is a schematic perspective view of a state in which a multilayer ceramic capacitor is mounted on a printed circuit board such that internal electrodes are perpendicular to the printed circuit board, according to another embodiment of the present invention, and FIG. 2B is a cross-sectional view of a state in which the multilayer ceramic capacitor of FIG. 2A is mounted on the printed circuit board.

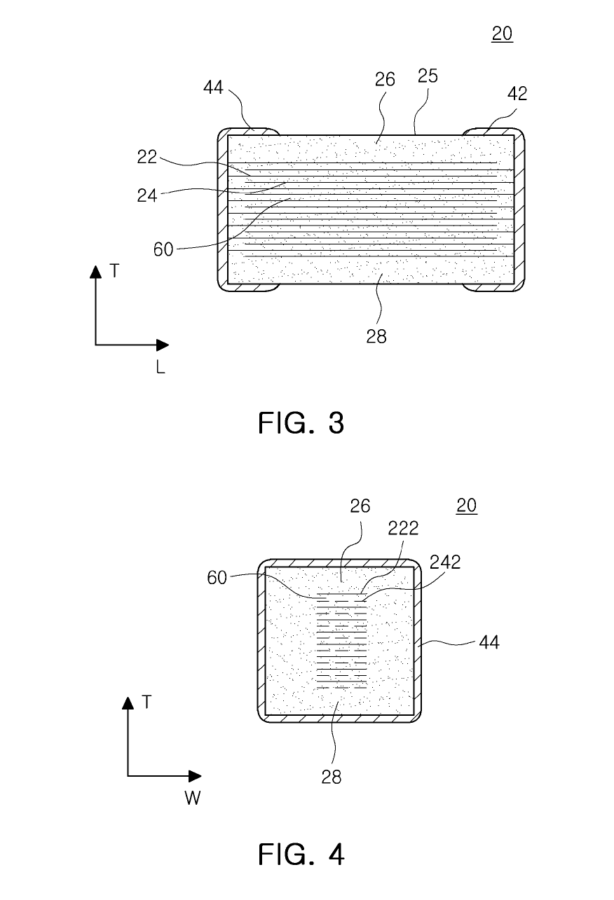

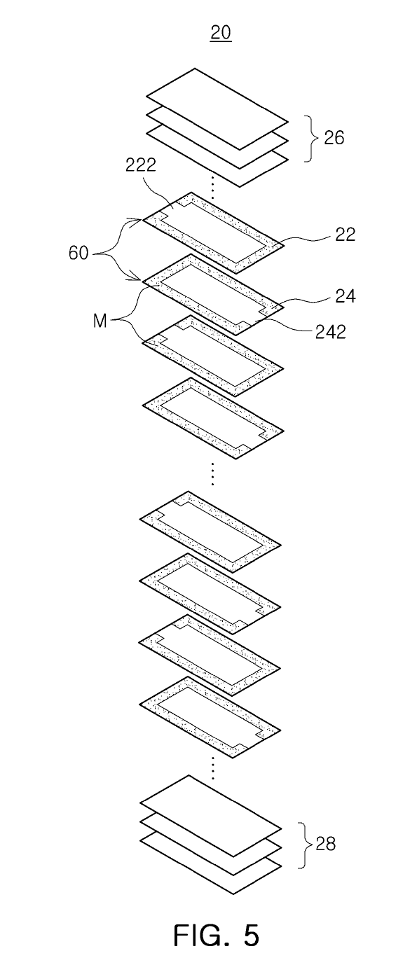

FIG. 3 is a cross-sectional view in a length-thickness direction of a multilayer ceramic capacitor according to an embodiment of the present invention; FIG. 4 is a cross-sectional view in a width-thickness direction of a multilayer ceramic capacitor according to an embodiment of the present invention; and FIG. 5 is a schematic exploded perspective view of a multilayer ceramic capacitor according to an embodiment of the present invention.

Referring to FIGS. 1 through 5, a multilayer ceramic capacitor 20 according to an embodiment of the present invention may include a ceramic body 25, external electrodes 42 and 44, internal electrodes 22 and 24, and dielectric layers 60.

The ceramic body 25 maybe formed by coating a conductive paste on each of ceramic green sheets to form the internal electrodes 22 and 24, laminating the ceramic green sheets having the internal electrodes 22 and 24 thereon, and sintering them. The ceramic body 25 may be formed by repeatedly laminating a plurality of the dielectric layers 60 and the internal electrodes 22 and 24.

The ceramic body 25 may have a hexahedral shape. When the ceramic body 25 is sintered in a chip shape, an appearance thereof may not be in a hexahedral shape having complete straight lines, due to sintering shrinkage of a ceramic powder. However, the ceramic body 25 may have substantially a hexahedral shape.

When directions of a hexahedron are defined in order to clearly describe embodiments of the present invention, L, W, and T shown in FIG. 1 indicate a longitudinal direction, a width direction, and a thickness direction, respectively. Here, the thickness direction (T) maybe used in the same concept as a lamination direction of internal electrodes in which the internal electrodes are laminated. In an embodiment of the present invention, the longitudinal direction (L) may be defined as a direction in which the internal electrodes 22 and 24 extend to the external electrodes 42 and 44 electrically connected thereto. The present invention may be applied to a multilayer ceramic electronic part of which the length in the longitudinal direction (L) is larger than the width (W), and may be also applied to a multilayer ceramic electronic part of which the length in the longitudinal direction (L) is smaller the width (W). Also, unlike the embodiment shown in FIGS. 1 through 5, the present invention may also be applied to a multilayer ceramic electronic part in which a plurality of external electrodes are all disposed on one external surface of the ceramic body.

The dielectric layers 60 and the internal electrodes 22 and 24 may be observed on a cross section of the sintered ceramic body 25 cut in a length-thickness direction (L-T) as shown in FIG. 3 (hereinafter, referred to as ‘L-T cross section’) and a cross section of the sintered ceramic body 25 cut in a width-thickness direction (W-T) as shown in FIG. 4 (hereinafter, referred to as ‘W-T cross section’).

As a material for the dielectric layer 60, a ceramic powder having a relatively high dielectric constant may be used in order to realize high capacitance. As the ceramic powder, for example, a barium titanate (BaTiO₃) based powder, strontium titanate (SrTiO₃) based powder, or the like may be used, but examples of the ceramic powder are not limited thereto.

The internal electrodes may include first internal electrodes 22 and second internal electrodes 24, and the first and second internal electrodes 22 and 24 may be electrically connected to the first and second external electrodes 42 and 44 through leads 222 and 224, respectively.

The first and second external electrodes 42 and 44 may be formed of a conductive paste including metal powders. As the metal powder included in the conductive paste, Cu, Ni, or an alloy thereof may be used, but examples of the metal powder are not limited thereto.

Here, the first and second internal electrodes 22 and 24 may be alternately and repeatedly laminated with the dielectric layer 60 therebetween. An active area part may be defined as each of portion of the internal electrodes 22 and 24, which overlap each other with the dielectric layer 60 interposed therebetween to contribute to forming of capacitance, on the L-T cross section of FIG. 3 and the W-T cross section of FIG. 4. The internal electrodes 22 and 24 may include the lead parts 222 and 242 connecting the active area parts to the external electrodes 42 and 44, respectively. The lead part has a width smaller than that of the active area part.

Also, in the ceramic body 25, margin parts M may be defined as portions of the dielectric layers 60 on which the internal electrodes 22 and 24 are not formed. Among the margin parts M, in particular, upper and lower margin parts M of the active area parts of the dielectric layers may be defined as upper and lower cover layers 26 and 28, and the active area parts of the dielectric layers on which the internal electrodes 22 and 24 are laminated with the dielectric layer interposed therebetween may be defined as active layers, which indicate a counter concept to the upper and lower cover layers 62 and 64.

The plurality of dielectric layers 60 constituting the ceramic body 25 are in a sintered state, and here, boundaries between the dielectric layers 60 may be integrated in one body such that they are difficult to distinguish from each other without a scanning electron microscope (SEM).

Meanwhile, the multilayer ceramic capacitor 20 according to an embodiment of the present invention may be miniaturized to have a standard size such that the length, width, and thickness of the ceramic body 25 are in ranges of 1.0±0.20 mm, 0.5+0.20 mm, and 0.5±0.20=(1005 size), respectively, or in ranges of 0.6±0.15 mm, 0.3±0.15 mm, and 0.3±0.15=(0603 size), respectively.

Also, in order to implement high capacitance (for example, 1 μF or higher for 1005 size or 0603-sized multilayer ceramic capacitors), the number of laminations of the internal electrodes 20 within the ceramic body 25 may be 170 layers to 500 layers.

### EXPERIMENTAL EXAMPLE

Hereinafter, the mounting method as shown in FIGS. 1A and 1B, by which the internal electrodes 22 and 24 have a directivity parallel with the printed circuit board 10, and the mounting method as shown in FIGS. 2A and 2B, by which the internal electrodes 22 and 24 have a directivity perpendicular to the printed circuit board 10, will be described in detail. Here, there will be description of an experimental example with respect to the occurrence of cracking in the internal electrodes due to warpage stress applied to the printed circuit board 10 when the shape and bottleneck rate of the lead parts 222 and 242 of the internal electrodes 22 and 24 are changed.

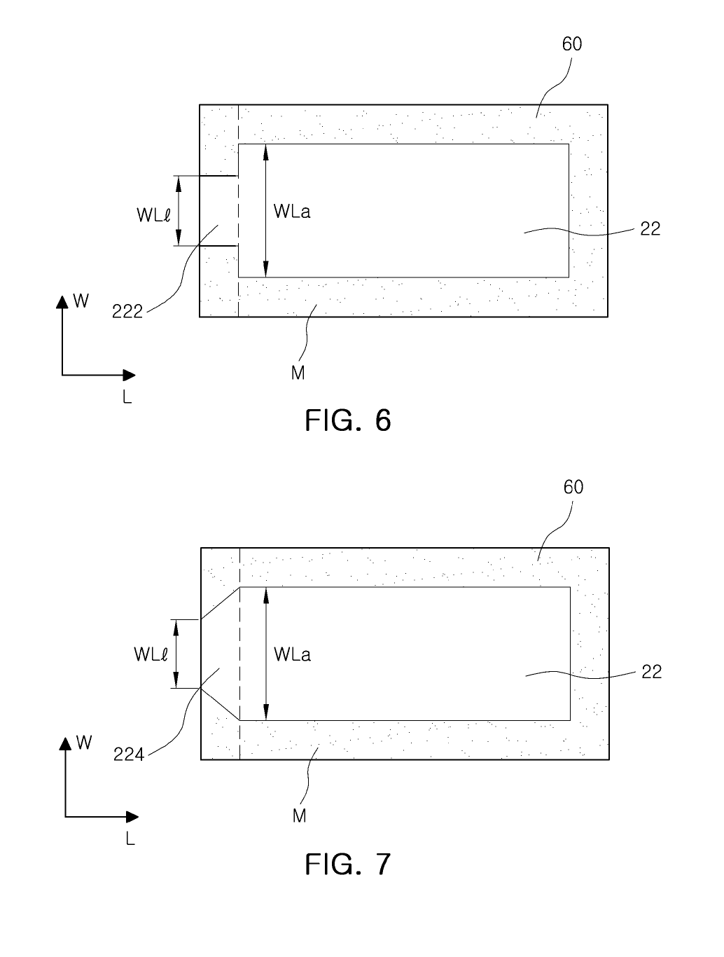

FIG. 6 is a schematic plane view in a length-width direction for measuring the bottleneck rate of a lead part of a multilayer ceramic capacitor according to an embodiment of the present invention; and FIG. 7 is a schematic plane view in a length-width direction for measuring the bottleneck rate of a lead part of a multilayer ceramic capacitor according to another embodiment of the present invention.

First, the shape and bottleneck rate of the lead parts 222 and 242 of the internal electrodes 22 and 24 according to an embodiment of the present invention will be described with reference to FIGS. 6 and 7.

Here, the term, the “bottleneck rate” may indicate the extent at which the width of the lead part is smaller than the width of the active area part in the internal electrode 22. The reason that the bottleneck rate is applied is because the amount of ions, moisture, and various kinds of small particles flowing into patterns of the internal electrodes maybe decreased when the external electrodes 42 and 44 are formed. In addition, the range of the bottleneck rate needs to be appropriately controlled since the warpage cracking severely occurs at the lead part of the internal electrode when warpage stress is generated in the printed circuit board during realization of miniaturization and high capacitance.

In the embodiments as shown in FIGS. 6 and 7, the bottleneck rate (α) maybe defined as 1−WL1/WLa, when the width of the active area part is defined as WLa and the width of the lead part 222 on one end portion of the ceramic body, which is connected to the external electrode, is defined as WL1.

According to an embodiment of the present invention, in cases of 1005 size or smaller multilayer ceramic capacitors, the bottleneck rate of the lead part may satisfy the range of 0<α≦0.12, regardless of whether the internal electrode 22 is mounted in parallel with or perpendicularly to the printed circuit board.

When the bottleneck rate α of the lead part is 0, there is not bottleneck rate in the lead part. When the bottleneck rate α of the lead part is 0.12 or higher, the occurrence of warpage cracking is frequent at the time of the vertical mounting of multilayer ceramic capacitor.

In addition, according to another embodiment of the present invention, in a case of a 0603-sized multilayer ceramic capacitor, the bottleneck rate of the lead part may satisfy the range of 0<α≦0.25 when the internal electrode 22 is mounted in parallel with the printed circuit board.

When the bottleneck rate α of the lead part is 0, there is no bottleneck rate in the lead part. When the bottleneck rate α of the lead part is 0.25 or higher, the capacitance obtainable, as compared with a target capacitance, may be relatively small due to an increase in ESR, and defective contact with the external electrodes may become relatively severe. As such, when the defective contact with the external electrodes becomes relatively severe, a defect in moisture resistance, such as permeation of moisture, may occur at the time of forming the external electrodes. Also, the occurrence of warpage cracking may be increased at the time of the parallel mounting.

According to another embodiment of the present invention, in a case of a 1005 size multilayer ceramic capacitor, the bottleneck rate of the lead part may satisfy the range of 0<α≦0.27 when the internal electrode 22 is mounted in parallel with the printed circuit board.

When the bottleneck rate α of the lead part is 0, there is no bottleneck in the internal electrode. When the bottleneck rate α of the lead part is 0.27 or higher, the capacitance obtainable, as compared with a target capacitance, maybe small due to an increase in ESR, and defective contact with the external electrodes may become relatively severe. As such, when the defective connection with the external electrodes becomes severe, a defect in moisture resistance such as permeation of moisture may occur at the time of forming the external electrodes. Also, the occurrence of warpage cracking may be increased at the time of the parallel mounting.

The lead part 222 according to an embodiment of the present invention may be implemented to have a square shape of which the width is uniform or a tapered shape of which the width is reduced toward a direction in which the lead part 222 is withdrawn to the external electrode.

Hereinafter, embodiments of the present invention will be specifically described with reference to experimental data of the inventive examples and comparative examples.

Each of various chip sized multilayer ceramic capacitors was mounted on a printed circuit board such that internal electrodes have a directivity parallel with or perpendicular to the printed circuit board, and then the occurrence frequency of warpage cracking to the warpage stress according to the range of bottleneck rate was measured for each of the multilayer ceramic capacitors. The measured results were tabulated in Table 1.

In the various chip sized multilayer ceramic capacitors used in experiments for obtaining the results of Table 1, the number of laminations of internal electrodes may be 170 layers to 500 layers in order to realize high capacitance thereof.

The multilayer ceramic capacitors according to the inventive examples and comparative examples of the present invention were manufactured as follows. A slurry including powders of barium titanate (BaTiO₃) and the like was coated and dried on carrier films, to prepare a plurality of ceramic green sheets formed in a thickness of 3.9 μm.

Then, a conductive paste for nickel internal electrodes was coated on the ceramic green sheets by using a screen such that patterns of the internal electrodes were provided on the ceramic green sheets, respectively, thereby forming the internal electrodes. Here, the width of the lead part was changed in order to implement the bottleneck rate of the lead part of the internal electrode.

Here, 250 layers of the ceramic green sheets were laminated, and then isostatic pressing was performed on this laminate at 85° C. under the pressure condition of 1000 kgf/cm². The ceramic laminate after completion of pressing was cut into individual chips, and then debindering was performed on the cut chips at 230° C. under air atmosphere for 60 hours.

Thereafter, firing was performed on the resultant chips in a reducing atmosphere under an oxygen partial pressure of 10⁻¹¹ atm˜10 ⁻¹⁰ atm, which is lower than the equilibrium oxygen partial pressure of Ni/NiO, such that the internal electrodes are not oxidized at 1150° C. or lower.

Here, the chips after firing were processed to have sizes of 1.0±0.20 mm×0.5±0.20 mm×0.5±0.20 mm (L×W×T) and 0.6±0.15 mm×0.3±0.15 mm×0.3±0.15 mm (L×W×T), that is, 1005 size and 0603 size, respectively.

Then, an external electrodes forming process, a plating process, and the like were performed to manufacture multilayer ceramic capacitors.

In the multilayer ceramic capacitor manufactured as described above, in order to measure the occurrence frequency of warpage cracking according to the bottleneck rate, a displacement of 2 mm was applied (a force of 44N) to a 1.6 T(mm) thickness substrate (an elastic modulus of 222.0±1.2N/cm) for 5 seconds, and then the occurrence frequency of warpage cracking was measured.

The occurrence of warpage cracking was observed by using an image, which was extracted from the image obtained by scanning a predetermined region through a scanning electron microscope (SEM), on a cross section cut in a width-thickness (W-T) direction at the central portion in a longitudinal direction of the ceramic body.

Also, fine crackings were analyzed through focused ion beam (FIB) processing.

Meanwhile, in order to confirm the reduction in contact characteristic between the external electrodes and the internal electrodes according to the increase in bottleneck rate, a test for checking defective contact was conducted by counting the number of multilayer ceramic capacitors having occurrence of defective contact among 1 million multilayer ceramic capacitors.

TABLE 1

| | | | | Occurrence | Occurrence | | |
|---|---|---|---|---|---|---|---|
| | | | | Frequency | Frequency | | |
| | | | | of | of | | |
| | | | | Warpage | Warpage | Capacitance | |
| | | | | Cracking in | Cracking in | (as Compared | |
| | | | Bottleneck | Parallel | Vertical | with Target | Defective |
| Sample | | Bottleneck | Rate, α | Mounting | Mounting | Capacitance) | Contact |
| No. | Size | Shape | (%) | (Number/40) | (Number/40) | (%) | (ppm) |
| 101* | 0603 | Square | 0 | 0 | 0 | 100 | 2 |
| 102 | | Bottleneck | 3 | 0 | 0 | 99.6 | 7 |
| 103 | | | 6 | 1 | 2 | 99.9 | 8 |
| 104 | | | 9 | 0 | 4 | 99.2 | 11 |
| 105 | | | 12 | 1 | 6 | 99.7 | 10 |
| 106 | | | 15 | 3 | 12 | 99.3 | 9 |
| 107 | | | 18 | 3 | 15 | 99.7 | 16 |
| 108 | | | 21 | 3 | 18 | 98.6 | 21 |
| 109 | | | 24 | 4 | 23 | 98.6 | 25 |
| 110* | | | 27 | 8 | 25 | 98.5 | 211 |
| 111* | | | 30 | 10 | 30 | 98.1 | 634 |
| 112* | | | 0 | 0 | 0 | 100 | 3 |
| 113 | | | 3 | 0 | 0 | 99.3 | 5 |
| 114 | | | 6 | 0 | 1 | 99.9 | 10 |
| 115 | | | 9 | 0 | 3 | 99.2 | 12 |
| 116 | | Tapered | 12 | 1 | 7 | 99.1 | 9 |
| 117 | | Bottleneck | 15 | 2 | 12 | 99.2 | 8 |
| 118 | | | 18 | 3 | 14 | 99.7 | 26 |
| 119 | | | 21 | 5 | 16 | 99.6 | 21 |
| 120 | | | 24 | 4 | 26 | 99.4 | 35 |
| 121* | | | 27 | 7 | 28 | 98.2 | 311 |
| 122* | | | 30 | 12 | 31 | 98.6 | 534 |
| 123* | 1005 | Square | 0 | 0 | 0 | 100 | 2 |
| 124 | | Bottleneck | 3 | 0 | 0 | 99.6 | 7 |
| 125 | | | 6 | 0 | 1 | 99.7 | 8 |
| 126 | | | 9 | 0 | 2 | 99.2 | 11 |
| 127 | | | 12 | 1 | 5 | 99.7 | 10 |
| 128 | | | 15 | 2 | 13 | 99.3 | 9 |
| 129 | | | 18 | 4 | 14 | 99.1 | 16 |
| 130 | | | 21 | 3 | 17 | 98.6 | 21 |
| 131 | | | 24 | 5 | 24 | 99.2 | 25 |
| 132 | | | 27 | 7 | 26 | 99.7 | 35 |
| 133* | | | 30 | 9 | 29 | 98.1 | 234 |
| 134* | | | 0 | 0 | 0 | 100 | 3 |
| 135 | | | 3 | 0 | 0 | 99.2 | 4 |
| 136 | | | 6 | 1 | 1 | 99.1 | 9 |
| 137 | | | 9 | 0 | 1 | 99.2 | 10 |
| 138 | | Tapered | 12 | 1 | 4 | 99.7 | 12 |
| 139 | | Bottleneck | 15 | 3 | 9 | 99.2 | 9 |
| 140 | | | 18 | 3 | 13 | 99.2 | 18 |
| 141 | | | 21 | 3 | 16 | 99.1 | 32 |
| 142 | | | 24 | 2 | 20 | 99.4 | 23 |
| 143 | | | 27 | 8 | 25 | 99.7 | 31 |
| 144* | | | 30 | 8 | 28 | 98.6 | 275 |

*Comparative Example

Table 1 shows results with respect to the occurrence of warpage cracking according to the bottleneck rate (α), capacitance obtained as compared with the target capacitance, and defective contact, when the lead part has a square shape or a tapered shape in 0603 size or 1005 size multilayer ceramic capacitors.

Comparative examples in 0603-sized multilayer ceramic capacitors are samples 101, 110, and 111 for a square bottleneck and samples 112, 121 and 122 for a tapered bottleneck. Also, comparative examples in 1005 size multilayer ceramic capacitors are samples 123 and 133 for a square bottleneck and samples 134 and 144 for a tapered bottleneck.

Referring to Table 1, in consideration of all of 1005 size and 0603-sized multilayer ceramic capacitors, the bottleneck rate of the lead part may satisfy the range of 0<α≦0.12, regardless of whether the internal electrodes 22 were mounted to have directivity parallel with or perpendicular to the printed circuit board.

When the bottleneck rate of the lead part a is above 0.12, it may be seen that the occurrence frequency of warpage cracking was increased in the 0603 size and 1005 size multilayer ceramic capacitors when the internal electrode was mounted vertically to the printed circuit board.

In addition, when the bottleneck rate of the lead part a is above 0.12, the occurrence frequency of warpage cracking was smaller when the internal electrode was mounted in parallel with the printed circuit board, as compared with when the internal electrode was mounted vertically to the printed circuit board.

However, it may be seen that, although the internal electrodes 22 are mounted in parallel with the printed circuit board, the occurrence frequency of warpage cracking was small when the bottleneck rate α was within a range of 0.25 in the 0603-sized multilayer ceramic capacitors, and the occurrence frequency of warpage cracking was small when the bottleneck rate a is within a range of 0.27 in the 1005 size multilayer ceramic capacitors.

In addition, it maybe seen that, although the internal electrodes 22 are mounted in parallel with the printed circuit board, in cases of the 0603-sized multilayer ceramic capacitors, the capacitance obtained as compared with the target capacitance was reduced and the number of multilayer ceramic capacitors having defective contact was also rapidly increased, when the bottleneck rate α is above 0.25. In addition, it may be seen that, in cases of the 1005 size multilayer ceramic capacitors, the capacitance obtained as compared with the target capacitance was reduced and the number of multilayer ceramic capacitors having defective contact was rapidly increased when the bottleneck rate α is above 0.27.

As set forth above, according to the multilayer ceramic electronic part of the embodiment of the present invention, occurrence of internal defects such as warpage and cracking may be reduced, even while the multilayer ceramic electronic part is miniaturized and has high capacitance, by relieving the internal stress concentrated on the lead part.

According to the multilayer ceramic electronic part of the embodiment of the present invention, a reliable multilayer ceramic electronic part having no internal defects and improved characteristics may be provided.

While the present invention has been shown and described in connection with the embodiments, it will be apparent to those skilled in the art that modifications and variations can be made without departing from the spirit and scope of the invention as defined by the appended claims.

What is claimed is:

1. A 1005 size or smaller multilayer ceramic electronic part, comprising:
a ceramic body having internal electrodes laminated therein, the internal electrodes having a directivity perpendicular to a printed circuit board; and
external electrodes formed on both end portions in a longitudinal direction of the ceramic body and electrically connected to the internal electrodes, each of the internal electrodes including an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part,
wherein when a width of the active area part is defined as WLa, the width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.12.

2. The multilayer ceramic electronic part of claim 1, wherein the lead part has a square shape having the same width.

3. The multilayer ceramic electronic part of claim 1, wherein the lead part has a tapered shape, a width of the tapered shape being reduced toward a direction in which the lead part is withdrawn to the external electrode.

4. The multilayer ceramic electronic part of claim 1, wherein the ceramic body has a length, a width, and a thickness of 1.0±0.20 mm, 0.5±0.20 mm, and 0.5±0.20 mm, respectively, or 0.6+0.15 mm, 0.3±0.15 mm, and 0.3±0.15 mm, respectively.

5. The multilayer ceramic electronic part of claim 1, wherein the internal electrodes are laminated in 170 layers to 500 layers in the ceramic body.

6. A multilayer ceramic electronic part of 0603 size, comprising:
a ceramic body having internal electrodes laminated therein, the internal electrodes having a directivity parallel with a printed circuit board; and
external electrodes formed on both end portions in a longitudinal direction of the ceramic body and electrically connected to the internal electrodes,
each of the internal electrodes including an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part,
wherein when a width of the active area part is defined as WLa, a width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.25.

7. The multilayer ceramic electronic part of claim 6, wherein the lead part has a square shape having the same width.

8. The multilayer ceramic electronic part of claim 6, wherein the lead part has a tapered shape, a width of the tapered shape being reduced toward a direction in which the lead part is withdrawn to the external electrode.

9. The multilayer ceramic electronic part of claim 6, wherein the ceramic body has a length, a width, and a thickness of 0.6±0.15 mm, 0.3±0.15 mm, and 0.3±0.15 mm, respectively.

10. The multilayer ceramic electronic part of claim 6, wherein the internal electrodes are laminated in 170 layers to 500 layers in the ceramic body.

11. A multilayer ceramic electronic part of 1005 size, comprising:
a ceramic body having internal electrodes laminated therein, the internal electrodes having a directivity parallel with a printed circuit board; and
external electrodes formed on both end portions in a longitudinal direction of the ceramic body and electrically connected to the internal electrodes,
each of the internal electrodes including an active area part and a lead part connecting the active area part and the external electrode to each other, the active area parts of the internal electrodes facing each other with the dielectric layer therebetween to contribute to forming capacitance, and the lead part of the internal electrode having a width smaller than that of the active area part, and
wherein when a width of the active area part is defined as WLa, a width of the lead part on one end portion of the ceramic body connected to the external electrodes is defined as WL1, and a bottleneck rate α of the lead part is defined as 1−WL1/WLa, the bottleneck rate α of the lead part satisfies a range of 0<α≦0.27.

12. The multilayer ceramic electronic part of claim 11, wherein the lead part has a square shape having the same width.

13. The multilayer ceramic electronic part of claim 11, wherein the lead part has a tapered shape, a width of the tapered shape being reduced toward a direction in which the lead part is withdrawn to the external electrode.

14. The multilayer ceramic electronic part of claim 11, wherein the ceramic body has a length, a width, and a thickness of 1.0±0.20 mm, 0.5±0.20 mm, and 0.5±0.20 mm, respectively.

15. The multilayer ceramic electronic part of claim 11, wherein the internal electrodes are laminated in 170 layers to 500 layers in the ceramic body.
